(19) United States
(12) Patent Application Publication
(10) Pub. No.: US 2021/0237869 A1
(43) Pub. Date: Aug. 5, 2021

(54) UNMANNED AERIAL VEHICLE

(71) Applicant: SZ DJI TECHNOLOGY CO., LTD., Shenzhen (CN)

(72) Inventors: Lei DENG, Shenzhen (CN); Xiaolong WU, Shenzhen (CN); Chuoying LU, Shenzhen (CN)

(21) Appl. No.: 17/212,615

(22) Filed: Mar. 25, 2021

Related U.S. Application Data
(63) Continuation of application No. PCT/CN2018/107695, filed on Sep. 26, 2018.

(51) Int. Cl. B64C 39/02; B64D 47/06; B64D 47/08

(52) U.S. Cl. CPC B64C 39/024; H05K 7/20854; B64D 47/08; B64D 47/06

(57) ABSTRACT

An unmanned aerial vehicle includes a frame, an avionics board assembly detachably mounted at a side of the frame, and a central board assembly detachably mounted at a top of the frame, spaced apart from the avionics board assembly, electrically connected to the avionics board assembly via a wire, and used to transfer at least one of a power signal or a communication signal. The avionics board assembly includes a flight controller used to control flight status of the unmanned aerial vehicle, and a positioning navigation device electrically connected to the flight controller and used to obtain current position information of the unmanned aerial vehicle.

### CROSS-REFERENCE TO RELATED APPLICATION

This application is a continuation of International Application No. PCT/CN2018/107695, filed Sep. 26, 2018, the entire content of which is incorporated herein by reference.

### TECHNICAL FIELD

The present disclosure relates to the field of aerial vehicle and, in particular, an unmanned aerial vehicle.

### BACKGROUND

Unmanned aerial vehicle (UAV) is an aerial device having the advantages of high speed, flexibility, and simple operation. With the development of technology, the use of UAV has gradually expanded from military and scientific research fields to various industries, such as electricity, communications, meteorology, agriculture, marine, and exploration, etc.

For a large aerial vehicle equipment, such as an agricultural spraying aircraft, a surveying and mapping aerial vehicle, etc., the UAV usually includes an avionics system and a central board main body. The avionics system is one of the core components of the UAV. The avionics system can implement the controlling of the UAV and the monitoring of the surrounding environment. The avionics system includes many electronic elements such as flight control circuit boards, wireless communication circuit boards, and various sensors. The central board main body is connected to the avionics system to provide power supplies of different specifications for the various circuit boards of the avionics system, and to realize functions such as internal communication or external communication of the UAV, thereby causing the avionics system to work normally. The power kit or load on the UAV issues instructions and allows the UAV to perform corresponding flight operations or other operations.

However, the avionics system and the central board main body of the current UAV are usually arranged at a single circuit board, which is exposed and mounted in the housing of the UAV. Therefore, there are many problems in the disassembly and post-maintenance of the circuit board of the avionics system and the central board main body.

### SUMMARY

In accordance with the disclosure, there is provided an unmanned aerial vehicle including a frame, an avionics board assembly detachably mounted at a side of the frame, and a central board assembly detachably mounted at a top of the frame, spaced apart from the avionics board assembly, electrically connected to the avionics board assembly via a wire, and used to transfer at least one of a power signal or a communication signal. The avionics board assembly includes a flight controller used to control flight status of the unmanned aerial vehicle, and a positioning navigation device electrically connected to the flight controller and used to obtain current position information of the unmanned aerial vehicle.

### BRIEF DESCRIPTION OF THE DRAWINGS

FIG. 1 is a perspective view of an unmanned aerial vehicle (UAV) consistent with embodiments of the disclosure.

FIG. 2 is a top view of the UAV shown in FIG. 1.

FIG. 3 is a schematic block diagram of the UAV shown in FIG. 1.

FIG. 4 is an exploded view of the UAV shown in FIG. 1.

FIG. 5 is a schematic electrical block diagram of the UAV shown in FIG. 1.

FIG. 6 is a perspective view of a first shock absorber shown in FIG. 4.

FIG. 7 is a front view of the UAV shown in FIG. 1.

FIG. 8 is a perspective view of a second shock absorber shown in FIG. 4.

Main reference numerals in the drawings are: Frame 10; Central body 11; Aerial vehicle arm 12; Support arm 14; Abutting platform 15; Convex post 16; Accommodation slot 17; Avionics board assembly 20; Flight controller 201; Positioning navigation device 202; First casing 21; First cover 211; First groove body 212; First heat dissipation fin 213; First gap 214; First lug 215; First port 216; Indicator light mounting opening 217; Image transmitter mounting opening 218; Camera mounting opening 219; Avionics board main body 22; First shock absorber 23; Annular groove 231; External antenna 24; Indicator light 25; Visual sensing device 26; Binocular camera 261; Image transmitter 262; Inertial measurement unit 27; Sensing system 28; Central board assembly 30; Power management circuit 301; Second casing 31; Second cover 311; Second groove body 312; Second heat dissipation fin 313; Second gap 314; Second lug 315; Second port 316; Connector interface 317; Central board main body 32; Second shock absorber 33; Electrical connector 34; Step portion 331; Fastening bolt 40.

### DETAILED DESCRIPTION OF THE EMBODIMENTS

Although the present disclosure can be easily expressed in different forms of embodiments, only some of the embodiments are described in detail in the specification with reference to the drawings. It is understood that this specification should be regarded as the exemplary description of the principle of the disclosure, which is not intended to limit the disclosure to what is described herein.

Therefore, a feature disclosed in the specification will be used to describe one of the features of an embodiment of the present disclosure, rather than implying that each embodiment of the present disclosure must have the described feature. In addition, it should be noted that many features are described in the specification. Although some features can be combined to illustrate possible system designs, these features can also be used in other combinations that are not explicitly stated. Thus, unless otherwise stated, the illustrated combinations are not intended to limit the embodiments of the present disclosure.

In the embodiments with reference to the drawings, the direction indications (such as up, down, left, right, front, and back) are used to explain that the structure and movement of various elements of the present disclosure are not absolutely but relatively. When an element is in a position shown in the drawing, the description is appropriate. If the description of the position of the element changes, the direction of the direction is also changed accordingly.

Example embodiments of the present disclosure will be further described in detail with reference to the accompany drawings below. In the case of no conflict, the following embodiments and features in the embodiments can be combined with each other.

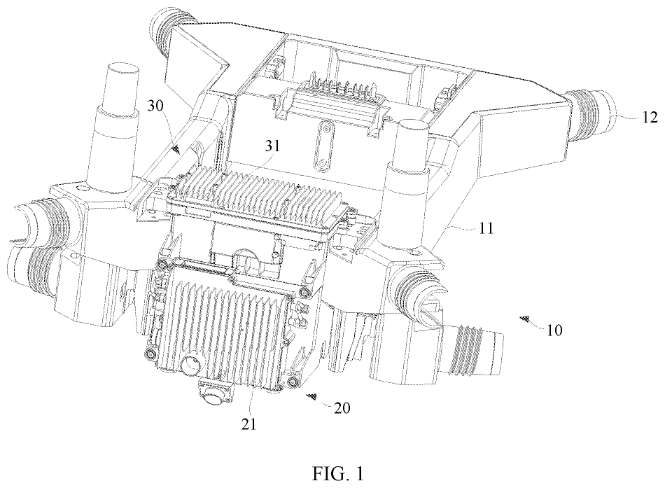

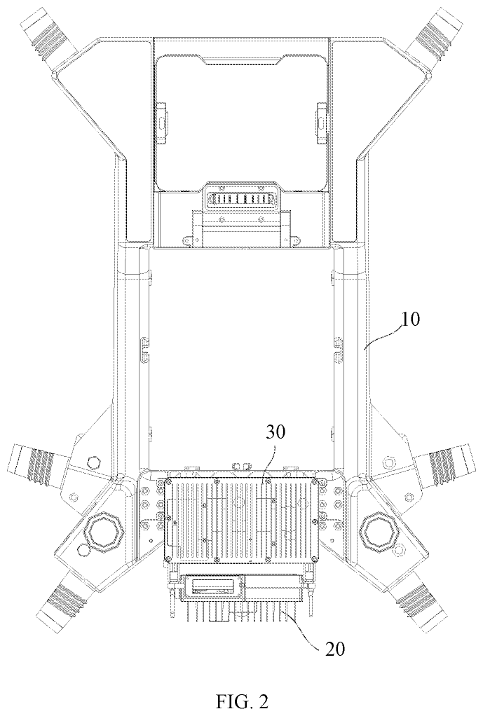

FIG. 1 is a perspective view of an unmanned aerial vehicle (UAV) consistent with embodiments of the disclosure. FIG. 2 is a top view of the UAV shown in FIG. 1. As shown in FIG. 1 and FIG. 2, the UAV includes a frame 10, an avionics board assembly 20, and a central board assembly 30.

The frame 10 includes a central body 11 and an aerial vehicle arm 12. The central body 11 is used to carry a flight control system, a power system, and etc. The aerial vehicle arm 12 is connected to the central body 11. The aerial vehicle arm 12 is used to connect a power propeller, and to provide power to the UAV.

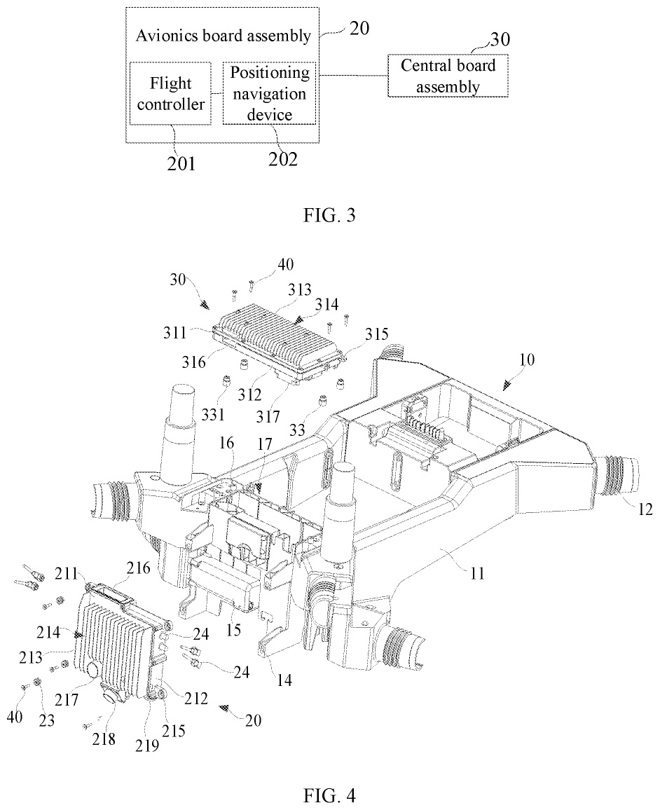

As shown in FIG. 3, the avionic board assembly 20 is detachably mounted at the side of the frame 10. The avionics board assembly 20 includes a flight controller 201 and a positioning navigation device 202. The flight controller 201 is used to control the flight status of the UAV. The positioning navigation device 202 is electrically connected to the flight controller 201, and is used to obtain the current position information of the UAV. The positioning navigation device 202 includes a global positioning system (GPS) unit.

The central board assembly 30 is detachably mounted at the top of the frame 10. The central board assembly 30 is used to transfer power signals and communication signals. The central board assembly 30 and the avionics board assembly 20 are spaced apart from each other. The central board assembly 30 is electrically connected to the avionics board assembly 20 via a wire.

The avionics board assembly 20 and the central board assembly 30 are two separate components, which are configured separately of each other. In addition, both the avionics board assembly 20 and the central board assembly 30 can be detachably mounted at the frame 10 to facilitate the mounting and maintenance of the avionics board assembly 20 or the central board assembly 30. When the avionic board assembly 20 or the central board assembly 30 is damaged, only the damaged component needs to be replaced, and the other component can still be used, which is convenient for maintenance and saves costs.

In some embodiments, the avionics board assembly 20 and the central board assembly 30 are provided at the front-end of the frame 10. The airflow at the front-end of the frame 10 is relatively large, which is beneficial to the heat dissipation of the avionics board assembly 20 and the central board assembly 30.

In some embodiments, the avionic board assembly 20 is provided at the front-end surface of the frame 10. The central board assembly 30 is provided at the upper top surface of the front-end of the frame 10. When the UAV is flying forward, the avionics board assembly 20 faces the oncoming airflow to ensure that the heat of the avionics board assembly 20 is dissipated as soon as possible.

In some embodiments, the avionic board assembly 20 includes a first casing 21 and an avionic board main body 22. The avionic board main body 22 is housed in the first casing 21.

The avionic board main body 22 is one of the core components of the UAV. The avionics board main body 22 can implement the controlling of the UAV and the monitoring of the surrounding environment. The avionic board main body 22 includes a wireless communication circuit board, various sensors, and many other electronic elements. The positioning navigation device 202 can be electrically connected to the flight controller 201 via the avionic board main body 22.

The central board main body 32 is connected to the avionic board main body 22 to realize providing power supplies of different specifications for each circuit board of the avionic board main body 22, and to realize the functions of internal communication or external communication of the UAV, thereby causing the avionic board main body 22 to work normally, to issue instructions to the power kit or load on the UAV, and to cause the UAV to perform corresponding flight operations or other operations.

The first casing 21 can be a metal casing. The metal casing has good heat conduction, which is beneficial to the overall heat dissipation of the avionic board assembly 20.

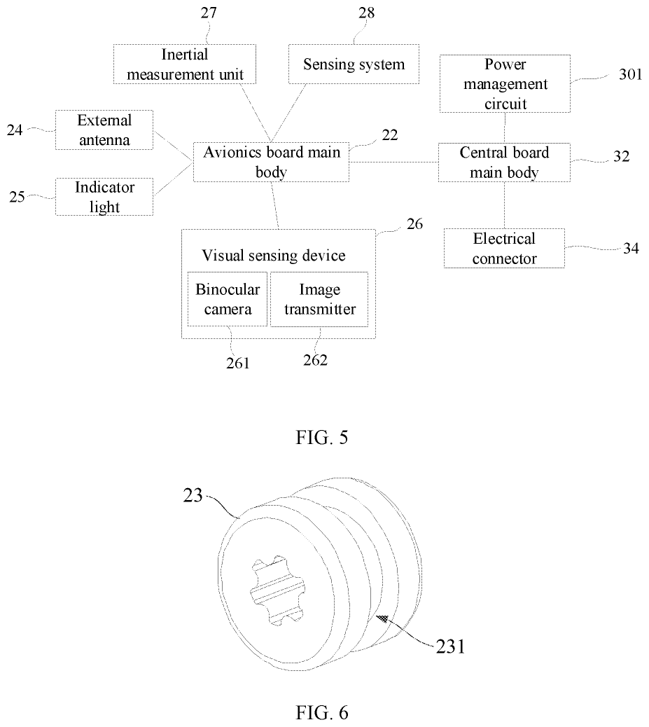

As shown in FIG. 4 and FIG. 5, the first casing 21 includes a first cover 211 and a first groove body 212. The first cover 211 and the first groove body 212 form a first housing cavity for housing the avionic board main body 22. The first cover 211 and the first groove body 212 are connected by screws, to allow the first cover 211 to be easily opened for inspection and maintenance of the avionic board main body 22 in the first housing cavity, and to ensure a stable connection between the first cover 211 and the first groove body 212 for maintaining the stability of the first casing 21.

The first casing 21 can also include a sealing ring (not shown). The sealing ring is provided between the first cover 211 and the first groove body 212 to seal the connection between the first cover 211 and the first groove body 212 for ensuring the sealing performance of the first casing 21.

The surface of the first casing 21 is configured with first heat dissipation fins 213. The first heat dissipation fins 213 are evenly provided at the outside of the first casing 21. In some embodiments, the first heat dissipation fins 213 are evenly provided at the outer surface of the first cover 211. The first heat dissipation fins 213 increase the surface area of the first casing 21 to increase the heat dissipation area for facilitating heat dissipation.

In addition, there are multiple first heat dissipation fins 213. There is a first gap 214 between the first heat dissipation fins 213, and the first gap 214 extends along the lifting direction of the UAV. The extending direction of the first gap 214 can realize better air flow that takes away heat quickly.

The first casing 21 is threadedly connected to the frame 10 by a fastening bolt 40.

A first lug 215 is provided at the rim of the first casing 21. The first lug 215 is configured with a screw hole, and the first lug 215 is threadedly connected to the frame 10 by a fastening bolt 40. The first casing 21 is configured with a first lug 215, which can avoid directly opening a screw hole on the edge of the first casing 21, and ensure the sealing performance of the first casing 21. In some embodiments, the first lug 215 is provided at the edge of the first groove body 212. It can be understood that the first lug 215 may be omitted, and the first casing 21 is directly connected to the frame 10.

The frame 10 is configured with a support arm 14. The end surface of the support arm 14 is configured with a screw hole, and the fastening bolt 40 is screwed into the screw hole with the first lug 215. There are multiple support arms 14 distributed in a rectangular shape. The first lug 215 at the edge of the first casing 21 corresponds to the support arm 14, and the avionic board assembly 20 and the frame 10 are maintained in a tight connection via the fastening bolt 40.

As shown in FIG. 6, the avionics board assembly 20 further includes a first shock absorber 23. The first shock absorber 23 is sleeved at the fastening bolt 40. The first shock absorber 23 can reduce the vibration between the avionic board assembly 20 and the frame 10. The fastening bolt 40 sequentially inserts across the first shock absorber 23 and the first lug 215 to connect to the frame 10. An annular groove 231 is provided at the first shock absorber 23 to enhance the shock-absorbing effect.

It can be understood that there may be more than one first shock absorber 23. The first shock absorber 23 can be a shock-absorption ring. The first shock absorber 23 may be made of a material such as rubber, latex, etc.

The frame 10 is configured with an abutting platform 15 for abutting against the middle of the first casing 21, and the abutting platform 15 is located between the support arms 14. The first casing 21 is connected to the frame 10 via the support arm 14. The support arms 14 bulge outward, and the four support arms 14 are distributed in a rectangular shape. Thus, there is a gap between the first groove body 212 and the frame 10 when the four top corners of the first casing 21 are correspondingly connected to the four support arms 14. That is, the abutting platform 15 is provided in the gap, and the surface of the abutting platform 15 supports the middle of the first groove body 212. The height of the abutting platform 15 is lower than the height of the support arms 14. The sum of the height of the abutting platform 15 and the height of the first groove body 212 is approximately equal to the height of the support arm 14. Therefore, the abutting platform 15 can provide a supporting force to the first casing 21 from the middle of the first casing 21. Then the middle of the first casing 21 is supported to cause the first casing 21 and the frame 10 to be connected stably, and to reduce the vibration of the first casing 21.

A first port 216 is also provided at the first casing 21. The avionic board main body 22 includes a wire for electrically connecting with the central board assembly 30, and the first port 216 is used for accommodating the wires. The wire passes across the first casing 21 via the first port 216, and then is electrically connected to the central board assembly 30.

The avionic board assembly 20 also includes an external antenna 24. An antenna port for receiving an external antenna 24 is provided at the side wall of the first casing 21. The external antenna 24 is used for receiving and transmitting signals. There are four antenna ports separately and symmetrically provided at the two side walls of the first casing 21. The external antenna 24 is electrically connected to the avionics board main body 22 via the antenna port. The antenna port is provided at a convex edge facing the outside of the first casing 21. The convex edge is used to mount and support the external antenna 24 to ensure that the external antenna 24 can be stably mounted at the first casing 21.

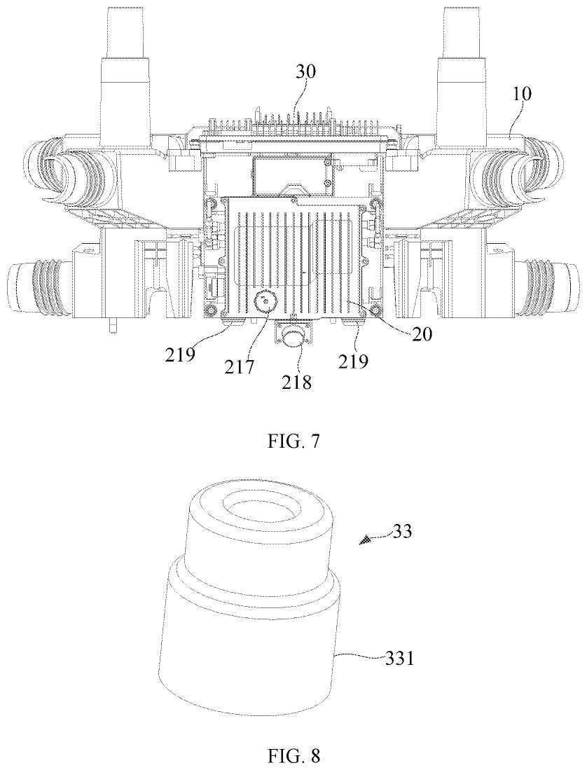

As shown in FIG. 4, FIG. 5, and FIG. 7, the visual sensing device 26 includes a binocular camera 261 and an image transmitter 262 (First Person View, refers as FPV). The binocular camera 261 is used to shoot video images. The image transmitter 26 is used to wirelessly transmit the video images captured by the camera mounted at the on-site UAV to the rear in real time. Where, the two lenses of the binocular camera 261 are optionally provided at both sides of the image transmitter 262, and an indicator light 25 is optionally provided in front of the image transmitter 262. The image transmitter 262 is mounted in the middle of the first cover 211, and the two lenses of the binocular camera 261 are separately mounted at the left and right sides of the image transmitter 262. The visual sensing device 26 is electrically connected to the avionic board main body 22.

Therefore, the first casing 21 is configured with an indicator light mounting opening 217, an image transmitter mounting opening 218, and a camera mounting opening 219, respectively. The indicator light mounting opening 217 is used to receive the indicator light 25. The image transmitter mounting opening 218 is used to receive the image transmitter 262. The camera mounting opening 219 is used to receive and fix the binocular camera 261. The two lenses of the binocular camera mounting opening 219 are optionally provided at two sides of the image transmitter mounting opening 218, and an indicator light mounting opening 217 is optionally provided in front of the image transmitter mounting opening 218. The image transmitter mounting opening 218 is mounted in the middle of the first cover 211, and the two lenses of the binocular camera mounting opening 219 are separately mounted at the left and right sides of the image transmitter mounting opening 218.

As shown FIG. 5, the avionics board assembly 20 also includes an inertial measurement unit 27 for sensing the current attitude of the UAV. The avionic board assembly 20 also includes a sensing system 28 for sensing the surrounding environment of the UAV. The sensing system 28 includes at least one of a monocular visual sensor, a binocular visual sensor, or an ultrasonic sensor. The central board assembly 30 is used to transfer power signals and communication signals. The central board assembly 30 includes a power management circuit 301, which is used to distribute electrical energy to the various electronic components of the UAV. The communication signals transferred by the central board assembly 30 include at least one of flight controlling signals, image data, sensing signals by the sensor, or power controlling signals.

The central board assembly 30 includes a second casing 31 and a central board main body 32. The central board main body 32 is housed in the second casing 31. The central board main body 32 carries the power management circuit 301.

The second casing 31 can be a metal casing. The metal casing has good heat conduction, which is beneficial to the overall heat dissipation of the central board assembly 30.

The second casing 31 includes a second cover 311 and a second groove body 312. The second cover 311 and the second groove body 312 constitute a second housing cavity for housing the central board main body 32. The second cover 311 and the second groove body 312 are connected by screws, to cause the second cover 311 to be easily opened for inspection and maintenance of the central board main body 32 in the second housing cavity, and to ensure a stable connection between the second cover 311 and the second groove body 312 for maintaining the stability of the second casing 31.

The second casing 31 can also include a sealing ring (not shown). The sealing ring is provided between the second cover 311 and the second groove body 312 to seal the connection between the second cover 311 and the second groove body 312 for ensuring the sealing performance of the second casing 31.

The surface of the second casing 31 is configured with second heat dissipation fins 313. The second heat dissipation fins 313 are evenly provided at the outside of the second casing 31. In some embodiments, the second heat dissipation fins 313 are evenly provided at the outer surface of the second cover 311. The second heat dissipation fins 313 increase the surface area of the second casing 31 to increase the heat dissipation area for facilitating heat dissipation.

In addition, there are multiple second heat dissipation fins 313. There is a second gap 314 between the second heat dissipation fins 313, and the second gap 314 extends along the front and rear flight direction of the UAV. The extending direction of the second gap 314 can realize better air flow that takes away heat quickly.

A second lug 315 is provided at the rim of the second casing 31, and the second lug 315 is threadedly connected to the frame 10 by a fastening bolt 40.

The frame 10 is configured with a convex post 16, and the convex post 16 is configured with a screw hole. The second lug 315 is threadedly connected to the convex post 16. The height of the convex post 16 is approximately equal to the thickness of the second groove body 312, to cause the bottom surface of the second groove body 312 to abut the frame 10, and to cause the second lug 315 to just abut the convex post 16, thereby ensuring a stable mounting of the second casing 31 on the frame 10.

The frame 10 is configured with an accommodation slot 17. The accommodation slot 17 is opposite to the second groove body 312, and is used for housing the second groove body 312. The shape of the accommodation slot 17 matches the shape of the second groove body 312. The accommodation slot 17 further restricts the second groove body 312 to ensure that the second casing 31 is stably mounted at the frame 10.

As shown in FIG. 8, the central board assembly 30 further includes a second shock absorber 33. The second shock absorber 33 is sleeved at the fastening bolt 40, and is located between the second lug 315 and the convex post 16. The second shock absorber 33 is used to reduce the vibration between the second lug 315 and the convex post 16.

The second shock absorber 33 includes a step portion 331. The step portion 331 is configured with a groove adapted to the shape of the convex post. The step portion 331 is sleeved at the outside of the convex post 16, and the convex post 16 is housed in the groove. The step portion 331 can completely cover the outer side of the convex post 16 to reduce the vibration between the second casing 31 and the convex post 16 better.

It can be understood that there may be more than one second shock absorber 33. The second shock absorber 33 may be made of a material such as rubber, latex, etc.

The second casing 31 is also configured with a second port 316 for electrical connection with the avionic board assembly 20. The second port 316 is configured opposite to the first port 216. The avionic board main body 22 and the central board main body 32 can be electrical connected via a wire passing across the first port 216 and the second port 316.

The central board assembly 30 includes an electrical connector 34. The electrical connector 34 is electrically connected to the central board main body 32. In addition, the second casing 31 is also configured with a connector interface 317 for accommodating the electrical connector 34. The connector interface 317 fixes the electrical connector 34. Components that need to be electrically connected to the central board main body 32 are electrically connected via the electrical connector 34.

Although the present disclosure has been described with reference to some typical embodiments, it should be understood that the terms used are illustrative and exemplary rather than restrictive. The present disclosure can be implemented in various forms without departing from the spirit or essence of the disclosure. It should be understood that the above-described embodiments are not limited to any of the foregoing details, but should be interpreted broadly within the spirit and scope of the disclosure. Therefore, all changes and modifications falling within the scope of the disclosure or equivalents thereof.

What is claimed is:

1. An unmanned aerial vehicle comprising:
a frame;
an avionics board assembly detachably mounted at a side of the frame and including:
a flight controller configured to control flight status of the unmanned aerial vehicle; and
a positioning navigation device electrically connected to the flight controller and configured to obtain current position information of the unmanned aerial vehicle; and
a central board assembly detachably mounted at a top of the frame, spaced apart from the avionics board assembly, electrically connected to the avionics board assembly via a wire, and configured to transfer at least one of a power signal or a communication signal.

2. The unmanned aerial vehicle of claim 1, wherein the avionics board assembly and the central board assembly are provided at a nose of the frame.

3. The unmanned aerial vehicle of claim 1, wherein the avionic board assembly includes:
a casing, the casing including a metal casing; and
an avionic board main body provided in the casing.

4. The unmanned aerial vehicle of claim 3, wherein the casing includes heat dissipation fins evenly provided at an outer side of the casing.

5. The unmanned aerial vehicle of claim 3, wherein a gap between two of the heat dissipation fins extends along a lift direction of the unmanned aerial vehicle.

6. The unmanned aerial vehicle of claim 3, wherein:
the casing includes a lug at a rim of the casing, the lug having a screw hole;
the casing is threadedly connected to the frame by a fastening bolt;
the avionic board assembly further includes a shock absorber sleeved at the fastening bolt; and
the fastening bolt sequentially passes through the shock absorber and the lug to connect to the frame.

7. The unmanned aerial vehicle of claim 3, wherein the frame includes a plurality of support arms distributed in a rectangular shape.

8. The unmanned aerial vehicle of claim 7, wherein the frame further includes an abutting platform located between two of the plurality of support arms and configured to hold a middle of the casing.

9. The unmanned aerial vehicle of claim 3, wherein:
the avionic board main body includes a wire configured to be electrically connected to the central board assembly; and
the casing includes a port configured to accommodate the wire.

10. The unmanned aerial vehicle of claim 3, wherein the casing includes an antenna port at a side wall of the casing and configured to receive an external antenna.

11. The unmanned aerial vehicle of claim 3, wherein:
the avionics board assembly further includes an indicator light and the casing includes an indicator light mounting opening configured to receive the indicator light; or
the avionics board assembly further includes an image transmitter and the casing includes an image transmitter mounting opening configured to receive the image transmitter.

12. The unmanned aerial vehicle of claim 3, wherein the casing includes a cover and a groove body, the cover and the groove body forming a housing cavity configured to house the avionics board main body.

13. The unmanned aerial vehicle of claim 1, wherein the central board assembly includes:
a casing; and
a central board main body provided in the casing.

14. The unmanned aerial vehicle of claim 13, wherein:
the casing includes a lug at a rim of the casing, the lug having a screw hole;
the casing is threadedly connected to the frame by a fastening bolt;
the central board assembly further includes a shock absorber sleeved at the fastening bolt; and
the fastening bolt sequentially passes through the shock absorber and the lug to connect to the frame.

15. The unmanned aerial vehicle of claim 13, wherein the casing includes heat dissipation fins evenly provided at the outer side of the casing.

16. The unmanned aerial vehicle of claim 15, wherein a gap between two of the heat dissipation fins extends along the front and rear flight directions of the unmanned aerial vehicle.

17. The unmanned aerial vehicle of claim 13, wherein the casing includes a port configured to accommodate a wire electrically connected to the avionic board assembly.

18. The unmanned aerial vehicle of claim 13, wherein:
the central board main body includes an electrical connector; and
the casing includes a connector interface configured to accommodate the electrical connector.

19. The unmanned aerial vehicle of claim 13, wherein the casing includes a cover and a groove body, the cover and the groove body sealed connected forming a housing cavity configured to house the central board main body.

20. The unmanned aerial vehicle of claim 19, wherein the frame further includes an accommodation slot opposite to the groove body and configured to house the groove body.
